(19) United States
(12) Patent Application Publication
(10) Pub. No.: US 2012/0033364 A1
(43) Pub. Date: Feb. 9, 2012

(54) DISPLAY APPARATUS

(75) Inventor: Kenji NONAKA, Kumagaya-shi (JP)

(73) Assignee: KABUSHIKI KAISHA TOSHIBA, Tokyo (JP)

(21) Appl. No.: 13/181,421

(22) Filed: Jul. 12, 2011

(30) Foreign Application Priority Data
Aug. 5, 2010 (JP) 2010-176653

(51) Int. Cl. H05K 5/00

(52) U.S. Cl. 361/679.01

(57) ABSTRACT

According to one embodiment, a display apparatus includes a rectangular front glass panel, a mounting fitting bonded to an inner surface of the front glass panel, arranged along a peripheral edge portion of the front glass panel, and including engaging pieces, a display panel superposed on the inner surface of the front glass panel and having a peripheral edge portion thereof held by the mounting fitting, and a decorative frame fitted to the mounting fitting to be mounted on the inner surface of the front glass panel and enclose the display panel. The decorative frame includes an engagement groove in engagement with the engaging pieces of the mounting fittings, an engaging protrusion configured to engage with the mounting fitting, and a slit formed at a bottom of the engagement groove so as to adjoin the engaging protrusion.

### CROSS-REFERENCE TO RELATED APPLICATIONS

This application is based upon and claims the benefit of priority from Japanese Patent Application No. 2010-176653, filed Aug. 5, 2010; the entire contents of which are incorporated herein by reference.

### FIELD

An embodiment described herein relates generally to a display apparatus comprising a front cover.

### BACKGROUND

In recent years, a number of large flat displays, such as liquid-crystal displays, plasma displays, etc., have been provided. These displays comprise a display panel, front cover, decorative frame, and back cover. The front cover covers at least the peripheral edge portion of the front surface of the display panel. The decorative frame is mounted on the peripheral edge portion of the panel. The back cover covers the back side of the display panel. Normally, the front cover and decorative frame are mounted on the display panel or front cover by separate mounting fittings or screws.

If the separate components are used to secure the decorative frame, as described above, the number of components increases, thus hindering reduction in the manufacturing cost of the display and improvement in productivity.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view showing a flat-panel television according to an embodiment;

FIG. 2 is an exemplary exploded perspective view showing the back side of the flat-panel television;

FIG. 3 is an exemplary perspective view showing the back side of the flat-panel television with its back cover removed;

FIG. 4 is an exemplary exploded perspective view showing a corner portion of a decorative frame, front panel, and mounting fittings;

FIG. 5 is an exemplary plan view showing the back side of the decorative frame;

FIG. 6 is an exemplary enlarged perspective view showing a part, e.g., a corner portion, of the decorative frame;

FIG. 7 is an exemplary sectional view of the decorative frame taken along line B-B of FIG. 6; and

FIG. 8 is an exemplary sectional view of the flat-panel television taken along line A-A of FIG. 3.

### DETAILED DESCRIPTION

Various embodiments will be described hereinafter with reference to the accompanying drawings.

In general, according to one embodiment, a display apparatus comprises: a rectangular front glass panel; a mounting fitting bonded to an inner surface of the front glass panel, arranged along a peripheral edge portion of the front glass panel, and comprising engaging pieces; a display panel superposed on the inner surface of the front glass panel and having a peripheral edge portion thereof held by the mounting fitting; and a decorative frame fitted to the mounting fitting to be mounted on the inner surface of the front glass panel and enclose the display panel and comprising an engagement groove in engagement with the engaging pieces of the mounting fittings, an engaging protrusion configured to engage with the mounting fitting, and a slit formed at a bottom of the engagement groove so as to adjoin the engaging protrusion.

An embodiment will now be described in detail with reference to the drawings.

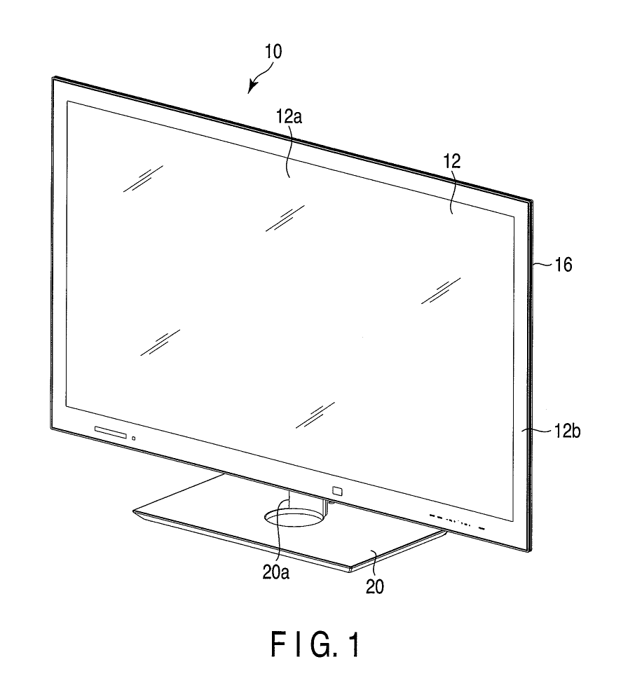

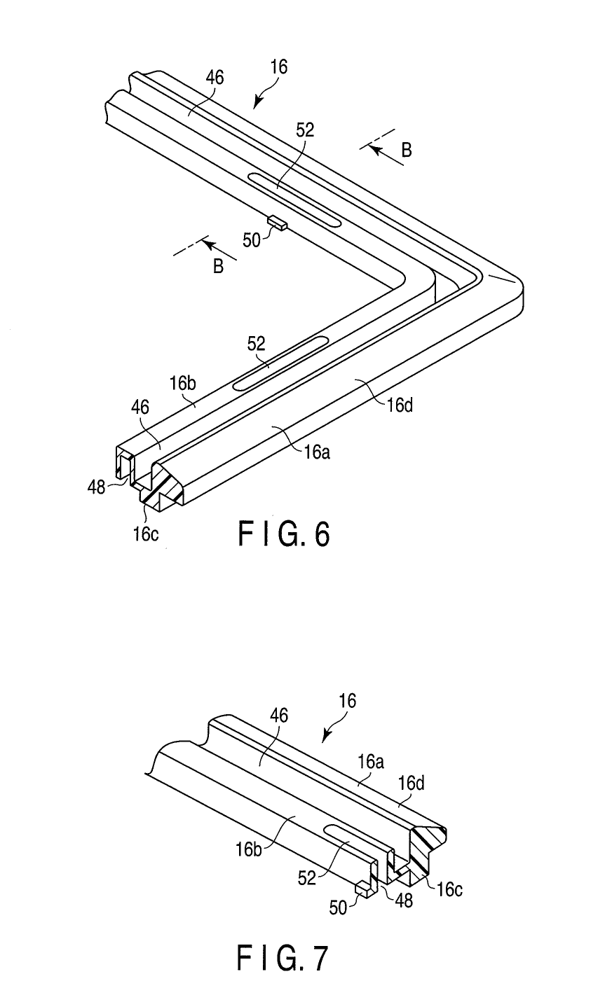

FIGS. 1 to 8 show a flat-panel television as a display apparatus according to the embodiment. The display apparatus to which the present invention is applicable is not limited to this type, and the invention is widely applicable to various display apparatuses.

As shown in FIGS. 1 to 3, a flat-panel television 10 comprises, for example, a rectangular front panel 12, display panel 14, rectangular decorative frame 16, back cover 18, and stand 20. The display panel 14 is superposed on the inner surface of the front panel 12. The decorative frame 16 encloses the display panel 14. The back cover 18 covers the back side of the display panel 14. The stand 20 supports the display panel 14 substantially vertically.

The front panel 12, which serves as a front cover, is formed of a transparent plate material, such as a transparent glass panel. The material of the front panel 12 is not limited to glass and may be a transparent resin plate or the like.

The display panel 14 may be, for example, a liquid-crystal display (LCD), plasma display, organic electroluminescent (EL) display, or the like. The display panel 14 comprises, for example, a liquid-crystal display panel and an optical sheet, backlight, etc. (not shown), on the back side of the liquid-crystal display panel. The peripheral edge portion of the front surface of the display panel 14, that is, a display surface, is held by a bezel (not shown), and the back side is covered by a metal frame 22. The display panel 14 is in the form of a flat, rectangular plate as a whole. The planar dimensions of the display panel 14 are slightly less than those of the front panel 12.

As shown in FIG. 1, the display panel 14 is located so that its surface overlaps the inner surface of the front panel 12, which forms a rectangular display surface 12a. The peripheral edge portion of the inner or outer surface of the front panel 12 is, for example, shade-printed with black mesh lines in a narrow width. Alternatively, a light-shielding film is affixed to the peripheral edge portion to form a picture-frame portion 12b, a rectangular frame.

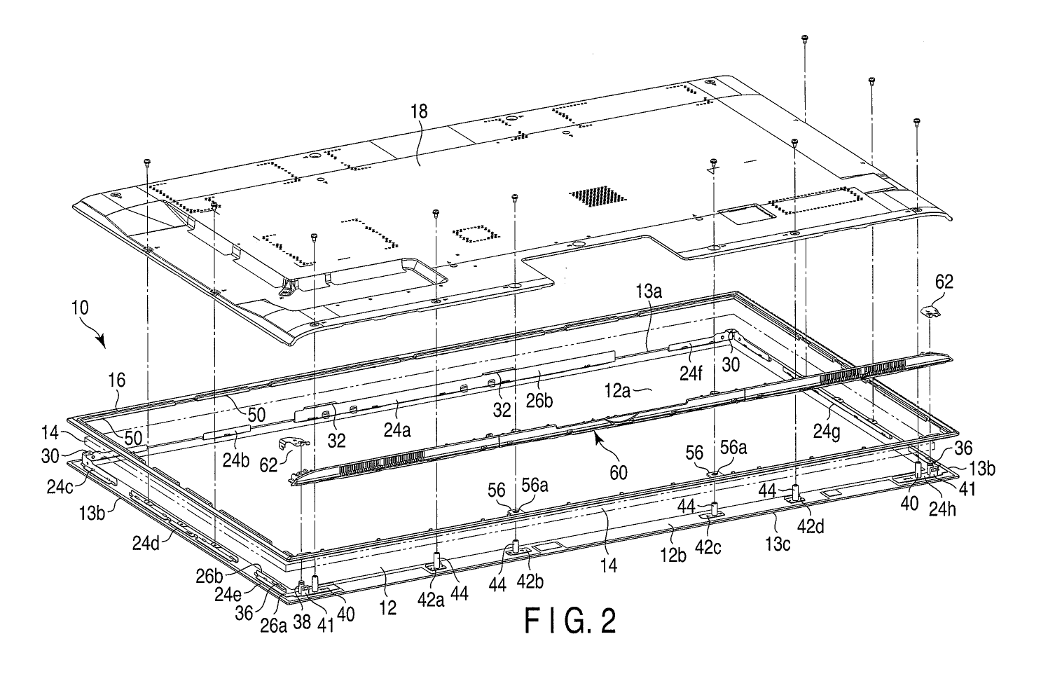

As shown in FIGS. 2 to 4 and 8, a plurality of mounting fittings 24a to 24h that individually function as mounting members are bonded to the peripheral edge portion of the inner surface of the front panel 12. Each mounting fitting is affixed to the inner surface of the front panel with, for example, a double-sided tape 15. The mounting fittings 24a to 24h are arranged intermittently or at appropriate intervals along a top side 13a and left and right lateral sides 13b of the front panel 12. The mounting fittings 24c, 24e, 24f and 24h are bent individually at right angles along the two upper corner portions and two lower corner portions of the front panel 12. The mounting fittings 24a to 24h are affixed to the inner surface of the picture-frame portion 12b of the front panel 12, that is, a shaded region, and are arranged so as not to be externally seeable through the display surface of the front panel 12. Although the mounting fitting means is formed of a plurality of divisions according to the present embodiment, it may alternatively be in the form of a continuous frame.

Each of the mounting fittings 24a to 24h is formed by bending an elongated flat metal plate into a substantially L-shaped cross-section, and comprises a bottom wall 26a and rising wall 26b. The bottom wall 26a is opposed parallel to the front panel 12 and affixed to the inner surface of the front panel with the double-sided tape 15. The rising wall 26b rises substantially at right angles to the inner surface of the front panel 12.

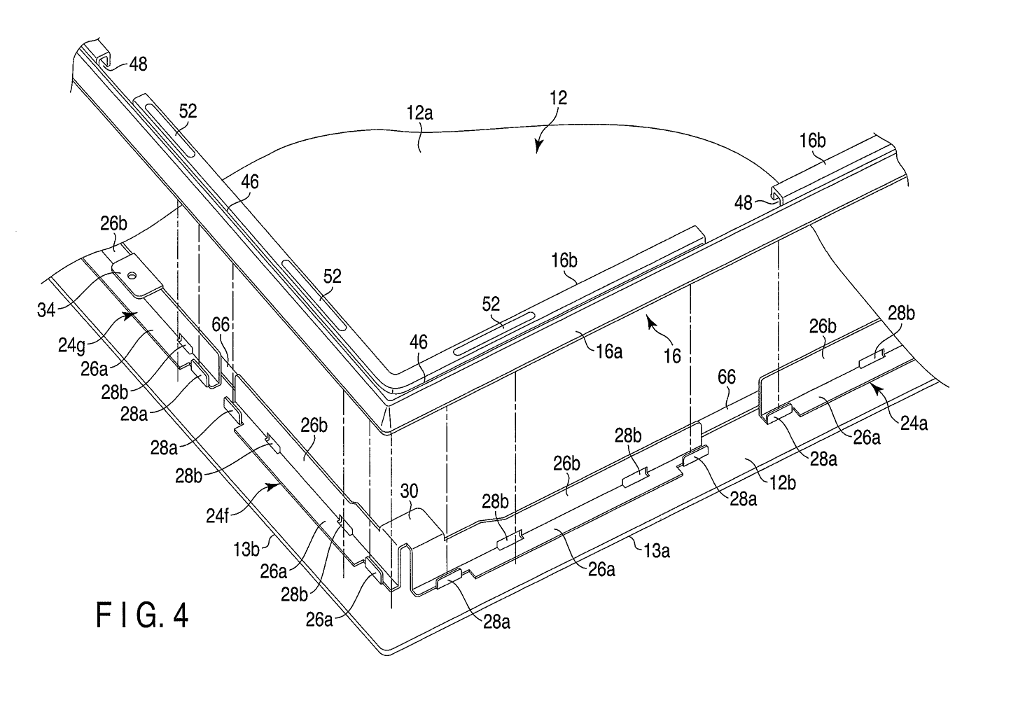

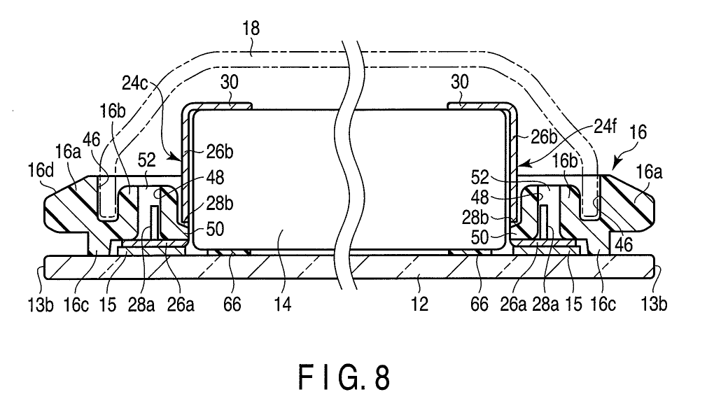

As shown in FIGS. 4 and 8, each of the mounting fittings 24a to 24h comprises at least one raised piece (engaging piece in this case) 28a and at least one engagement hole 28b. The engaging piece 28a is formed by cutting and raising a part of the bottom wall 26a at right angles and is opposed to the rising wall 26b with a gap therebetween. The engagement hole 28b is formed at the boundary between the bottom wall 26a and rising wall 26b, in a position slightly deviated from the engaging piece 28a. In the present embodiment, the engaging pieces 28a and engagement holes 28b are formed at longitudinally spaced positions in each of the relatively long mounting fittings 24a, 24d and 24g. The engaging pieces 28a and engagement holes 28b are formed at both sides of each corner portion and at extended end portions of each of the right-angled mounting fittings 24c and 24f at the corner portions.

Each of the two mounting fittings 24c and 24f at the two upper corner portions of the front panel 12 integrally comprises a bridge portion or retaining portion 30, which extends across its corresponding right-angled corner portion and is opposed substantially parallel to the front panel with a predetermined space therebetween.

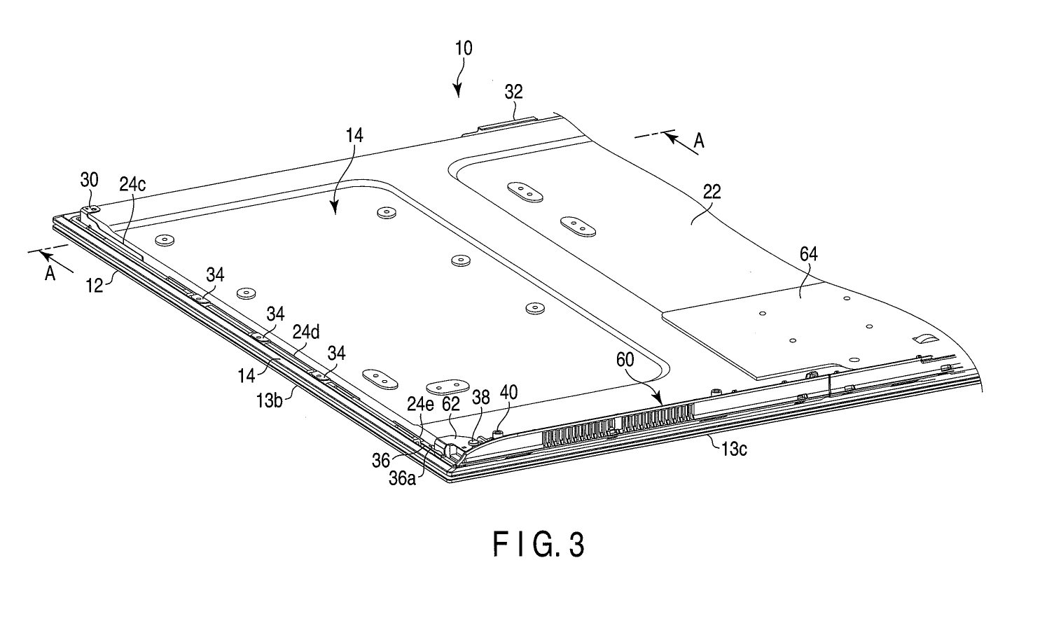

As shown in FIGS. 2 and 3, the mounting fitting 24a on the top side 13a of the front panel 12 integrally comprises a plurality of hook portions 32, which extend from the upper end of the rising wall 26b toward the display panel 14. As shown in FIGS. 3 and 4, each of the mounting fittings 24d and 24g on the lateral sides 13b of the front panel 12 integrally comprises a plurality of fixed brackets 34, each of which extends from the upper end of the rising wall 26b on the opposite side to the display panel 14 and is formed with a threaded hole. The fixed brackets 34 are arranged at predetermined intervals along the side edges of the front panel 12.

As shown in FIGS. 2 and 3, each of the mounting fittings 24e and 24h disposed at the opposite corner portions on a lower side 13c of the front panel 12 integrally comprises the L-shaped bottom wall 26a and rising wall 26b. The rising wall 26b rises at right angles from the bottom wall 26b on the lateral side of the front panel 12. Each of the mounting fittings 24e and 24h integrally comprises an engaging bracket 36, which extends from the upper end of the rising wall 26b on the opposite side to the display panel 14 and is formed with the an engagement hole 36a. The engagement hole 36a is a slot extending parallel to each lateral side 13b of the front panel 12. A columnar engaging pin 38 and boss 40 are set up on that part of the bottom wall 26a which extends along the lower side 13c of the front panel 12. A threaded hole is formed in the boss 40. Further, a locking bracket 41 is set up on the bottom wall 26a so as to extend at right angles to the front panel 12.

As shown in FIG. 2, a plurality (e.g., four) of metal fixtures 42a to 42d in the form of rectangular plates are bonded to a peripheral edge portion on the lower side of the inner surface of the front panel 12 and are arranged at intervals along the lower side 13c of the front panel 12. A columnar boss 44 is set up on each of the metal fixtures 42a to 42d and extends at right angles to the front panel 12. A threaded hole is formed in each boss 44.

The front panel 12, display panel 14, and decorative frame 16 are secured together by the mounting fittings 24a to 24h. As shown in FIGS. 2 to 8, the decorative frame 16 comprises a rectangular frame body 16a and fixed frame portions 16b. The fixed frame portions 16b are arranged continuously or intermittently along the opposite lateral sides and top side of the frame body on the inner peripheral side of the frame body. The decorative frame 16 is integrally formed of an elastic material, such as a synthetic resin. The frame body 16a has an external size and shape substantially equal to those of the front panel 12.

The frame body 16a comprises a projection 16c, which projects toward the front panel 12 so as to be able to contact the inner surface of the front panel. The projection 16c is continuous throughout the circumference of the frame body. A slope 16d is formed on the back side of the frame body 16a, that is, on the opposite side to the front panel 12, so as to cover the entire circumference. A retaining groove 46 that opens to the back side of the frame body 16a is defined between the frame body 16a and the fixed frame portions 16b. The retaining groove 46 continuously extends along the opposite lateral sides and top side of the frame body 16a. The peripheral edge portion of the back cover 18 (described later) is configured to be fitted in the retaining groove 46.

The fixed frame portions 16b of the decorative frame 16 have a substantially U-shaped cross-section and each integrally comprise a pair of peripheral walls extending along each side of the front panel 12 and a bottom wall extending parallel to the front panel with a gap therebetween. Each fixed frame portion 16b defines an engagement groove 48 that opens to the front panel 12. At each of the opposite corner portions of the frame body 16a on the top side 13a, each fixed frame portion 16b is continuously bent at right angles along the corner portion.

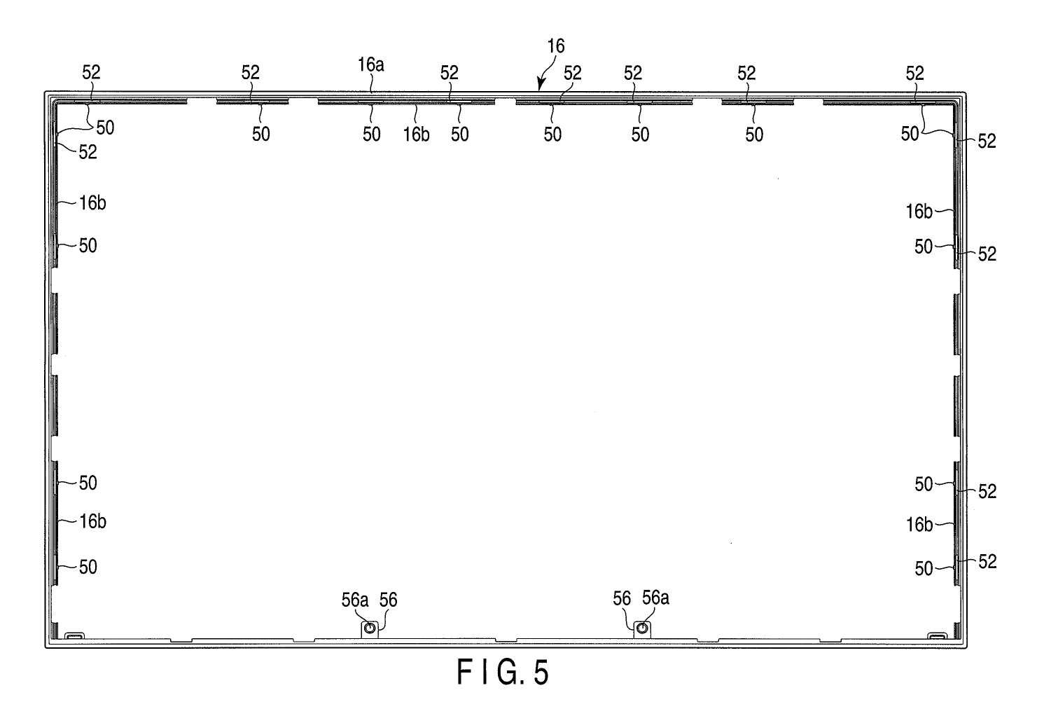

As shown in FIGS. 5 to 8, engaging protrusions or lugs 50, e.g., eight at the top side portion of the decorative frame 16 and four at each lateral side portion, are integrally disposed on the fixed frame portion 16b. The engaging protrusions 50 are arranged at predetermined intervals along each side of the decorative frame 16. At each top-side corner portion of the decorative frame 16, the engaging protrusions 50 are disposed on the opposite sides of each corner.

As shown in FIGS. 2 and 5 to 8, each engaging protrusion 50 projects inwardly relative to the decorative frame 16, that is, toward the display panel 14, from the front-panel side end of the inner peripheral wall of each fixed frame portion 16b. As described later, each engaging protrusion 50 is configured to be able to engage with the engagement hole 28b of its corresponding mounting fitting.

A slit 52 is formed penetrating the bottom wall of that part of each fixed frame portion 16b on which each engaging protrusion 50 is disposed and communicates with the engagement groove 48. The slit 52 extends parallel to a side of the decorative frame 16 and overlaps the engaging protrusion 50. The slit 52 facilitates that part of the fixed frame portion 16b on which the engaging protrusion 50 is disposed to be relatively easily elastically deformed. Thus, the engaging protrusion 50 can be easily caught by the engagement hole 28b of its corresponding mounting fitting.

As shown in FIGS. 2 and 5, the lower side portion of the frame body 16a comprises a plurality (e.g., two) of engaging pieces 56. These engaging pieces 56 protrude from the frame body 16a toward the display panel 14 and opposed parallel to the front panel. A through-hole 56a is formed in each engaging piece 56.

The decorative frame 16 constructed in this manner is attached to the mounting fittings 24a to 24h and secured to the front panel 12 so as to enclose the display panel 14. As shown in FIGS. 3, 4, 6 and 8, the entire decorative frame 16 is put on the mounting fittings 24a to 24h from above. The fixed frame portions 16b of the decorative frame 16 are placed individually on the bottom walls 26a outside the rising walls 26b of the mounting fittings 24a to 24h. When this is done, the engaging pieces 28a of the mounting fittings 24a to 24h are caused individually to engage with the engagement grooves 48 of the fixed frame portions 16b so that the peripheral walls of the frame portions 16b are interposed between the engaging pieces 28a and rising walls 26b. Further, the engaging protrusions 50 on the fixed frame portions 16b are anchored individually to the engagement holes 28b of the mounting fittings 24a to 24h. As this is done, the engaging protrusions 50 can be easily caused to engage with the engagement holes 28b of the mounting fittings by deforming the fixed frame portions 16b in the positions of the slits 52. Since those parts of the fixed frame portions 16b of the decorative frame 16 which correspond individually to the fixed brackets 34 of the mounting fittings 24d and 24g and the engaging brackets 36 are removed, the decorative frame 16 can be attached to the mounting fittings 24a to 24h without being caught by the fixed brackets or locking brackets 41. Thus, the decorative frame 16 is secured to the mounting fittings and front panel 12 and encloses the mounting fittings 24a to 24h and display panel 14 in such a manner that the fixed frame portions 16b cover the bottom walls 26a of the mounting fittings and that the projection 16c is in contact with the inner surface of the front panel 12.

The lower side portion of the frame body 16a is located in contact with the inner surface of the front panel 12, and the bosses 44 of the metal fixtures 42b and 42c are passed individually through the through-holes 56a of the engaging pieces 56. As the engaging pieces 56 engage with the bosses 44, the lower side portion of the frame body 16a is positioned relative to the front panel 12.

On the lower side of the front panel 12, as shown in FIGS. 2 and 3, an elongated bottom plate 60 is placed on the decorative frame 16. The bottom plate 60 comprises three members, e.g., a central member and two side members, which are connected to one another. The bottom plate 60 comprises engagement portions that engage with the bosses 44 on the metal fixtures 42a to 42d and engagement portions that engage with the engaging pins 38 and bosses 40 on the mounting fittings 24e and 24h. Thus, the bottom plate 60 is mounted on the front panel 12 so as to be set up along the lower side of the front panel.

As shown in FIGS. 2, 3 and 8, the display panel 14 is superposed on the front panel 12 with its display surface opposed to the inner surface of the front panel. As the display panel 14 is slid to the upper side of the front panel, its periphery contacts the rising walls 26b of the mounting fittings 24a to 24h. Consequently, the display panel 14 is prevented from moving along the plane of the front panel 12 and held in position. The opposite upper corner portions of the display panel 14 are individually fitted between the front panel 12 and the retaining portions 30 of the mounting fittings 24c and 24f. Further, the opposite lower corner portions of the display panel 14 are individually pressed from above by the engaging pins 38 of the mounting fittings 24e and 24h and metal fixtures 62 attached to the engaging brackets 36. Thus, the display panel 14 is prevented from moving at right angles to the inner surface of the front panel 12 and held in a position where it contacts the front panel.

As shown in FIGS. 4 and 8, band-like gaskets 66 formed of, for example, rubber sheets are affixed to those parts of the inner surface of the front panel 12 which face the outer peripheral portion of the display panel 14. The display panel 14 contacts the inner surface of the front panel 12 with the gaskets 66 therebetween.

A liquid-crystal driver circuit board, controller board, power circuit board, etc. (not shown), are mounted on the back surface of the display panel 14. As shown in FIG. 3, a rectangular baseplate 64 is secured to a lower central portion of the back surface of the display panel 14 by screws. A leg portion 20a (FIG. 1) of the stand 20 is secured to the baseplate 64.

As shown in FIGS. 2 and 8, the respective back surfaces of the front panel 12 and display panel 14 are covered by the back cover 18. The back cover 18 is formed of a substantially rectangular metal plate, and its upper side portion and opposite lateral side portions are curved toward the front panel 12 with their end edge portions bent at right angles. The back cover 18 is attached to the decorative frame 16 in such a manner that the end edge portions of the top and lateral side portions are fitted in the retaining groove 46 of the decorative frame 16 and covers the back surface of the display panel 14 and the mounting fittings. The lower side portion of the back cover 18 is superposed on the bottom plate 60. Further, the back cover 18 is externally attached by screws to the fixed brackets 34 of the mounting fittings, bosses 40 and 44, and screw retaining portions (not shown) on the back surface of the display panel 14.

According to the flat-panel television 10 constructed in this manner, the display panel 14, decorative frame 16, and front panel 12 are fixedly mounted together by the mounting fittings 24a to 24h bonded to the front panel. Specifically, the decorative frame 16 is secured to the front panel 12 so as to enclose the display panel 14 by being attached to the mounting fittings 24a to 24h. Thus, it is unnecessary to use independent fixing members, screws, etc., to mount the decorative frame 16, so that the number of components can be reduced, the structure of the flat-panel television simplified, and the manufacturing cost reduced. Further, the decorative frame 16 can be secured to the front panel 12 simply by being fitted to the engaging pieces 28a and engagement holes 28b of the mounting fittings, so that the assemblability can be improved. At the same time, the display panel 14 can be more easily mounted on the front panel 12 by means of the mounting fittings 24a to 24h and metal fixtures 62 without using screws, so that the manufacturing cost can be reduced and the assembly efficiency improved.

The decorative frame 16 may have an outside diameter less than that of the front panel 12 so that it can be superposed within the range of the inner surface of the front panel. Thus, the decorative frame 16 does not project outward from the outer periphery of the front panel 12, so that the picture-frame part of the display surface can be made narrow.

Although the divided mounting fittings are configured to be secured to the front panel, they may be replaced with a single metal fitting in the form of a continuous frame. In the case where the divided mounting fittings are used as in the present embodiment, they may be adapted to televisions and display panels of various sizes by changing the intervals between the mounting fittings according to the television size.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The display apparatus of the present invention is not limited to a flat-panel television and is also applicable to, for example, a display for a personal computer. In addition, the display apparatus may be embodied in modified forms without departing from the spirit of the invention. Although the front cover has been described as the front panel in the form of a rectangular plate, it may alternatively be, for example, a panel in the form of a rectangular frame that allows the display surface of the display panel to be externally exposed.

What is claimed is:

1. A display apparatus comprising:
a rectangular front glass panel;
a mounting fitting attached to an inner surface of the front glass panel, arranged along a peripheral edge portion of the front glass panel, and comprising engaging parts;
a display panel superposed on the inner surface of the front glass panel and having a peripheral edge portion held by the mounting fitting; and
a decorative frame fitted to the mounting fitting, the decorative frame mountable on the inner surface of the front glass panel and configured to enclose the display panel, and comprising an engagement groove engaged with the engaging parts of the mounting bracket, an engaging protrusion configured to engage with the mounting fitting, and a slit formed at a bottom of the engagement groove next to the engaging protrusion.

2. The display apparatus of claim 1, wherein the mounting fitting is arranged along at least a plurality of sides of the front glass panel and integrally comprise a bottom wall attached to the inner surface of the front glass panel, a rising wall extending from the front glass panel and facing a side surface of the display panel, and a rising part from the bottom wall, facing the rising wall with a gap therebetween, and comprising at least a portion of the engaging parts.

3. The display apparatus of claim 2, wherein the decorative frame comprises a frame body comprising a projection in contact with the inner surface of the front glass panel, and a fixed frame portions disposed along sides of the frame body on the inner peripheral side of the frame body, wherein the engagement groove are formed in the fixed frame portions and in engagement with the engaging parts of the mounting fitting.

4. The display apparatus of claim 2, wherein the engaging protrusion of the decorative frame projecting from the fixed frame portions engages with an engagement hole in the mounting fitting, and the slit are formed in the fixed frame portions near the engaging protrusion.

5. The display apparatus of claim 3, further comprising a back cover which covers the mounting fittings and a back surface of the display panel, wherein
the decorative frame comprises a fixing groove extending along sides of the frame body, and
a peripheral edge portion of the back cover is fitted in the fixing groove.

6. A display apparatus comprising:
a front cover;
a display panel superposed on an inner surface side of the front cover;
a decorative frame enclosing the display panel; and
a mounting member attached to the inner surface of the front cover and configured to hold the front cover, the display panel, and the decorative frame to one another.

7. The display apparatus of claim 6, wherein the mounting member comprises an engaging part engaged with an engagement groove of the decorative frame.

8. The display apparatus of claim 7, wherein the decorative frame comprises an engaging protrusion disposed near the engagement groove in engagement with the engaging part of the mounting member and configured to engage with the mounting member.

9. The display apparatus of claim 8, wherein the decorative frame comprises a slit formed at a bottom of the engagement groove next the engaging protrusion.
